(19) United States
(12) Patent Application Publication
(10) Pub. No.: US 2015/0100255 A1
(43) Pub. Date: Apr. 9, 2015

(54) METHOD FOR LOCATING FAULTS IN A POWER NETWORK HAVING FAULT INDICATORS

(71) Applicant: I-SHOU University, Kaohsiung (TW)

(72) Inventors: JEN-HAO TENG, Kaohsiung (TW); SHANG-WEN LUAN, Kaohsiung (TW); CHAO-SHUN CHEN, Kaohsiung (TW); YI-CHENG LIN, Kaohsiung (TW); WEI-HAO HUANG, Kaohsiung (TW)

(73) Assignee: I-SHOU University, Kaohsiung (TW)

(21) Appl. No.: 14/049,886

(22) Filed: Oct. 9, 2013

(51) Int. Cl. G01R 31/08

(52) U.S. Cl. CPC G01R 31/088
USPC 702/59

(57) ABSTRACT

A method for locating faults in a power network includes reading power network information stored in a database in a data reading step. A power network matrix is created based on the power network information in a power network creating step. A fault current vector is created in a fault current vector creating step. In a fault locating step, a backward substitution is carried out on the fault current vector and the power network matrix to obtain a detection zone vector, and the fault can be located. The fault locating speed of the power network is, thus, increased.

### BACKGROUND OF THE INVENTION

1. Field of the Invention

The present invention relates to a method for locating faults in a power network having a plurality of fault indicators and, more particularly, to a method for rapidly locating faults in a power network with a plurality of fault indicators.

2. Description of the Related Art

A power network is the main medium for transmitting power from a power company to user ends. To maintain stable power transmission, the power company generally installs a plurality of fault indicators in the power network to monitor the power transmission status and the locations of fault currents. Thus, the power company can immediately know the operation of the power network and can locate the faults in the network.

FIG. 1 shows a conventional power network 7 including at least one feed line 71 in which power flows from an upstream end 72 to a downstream end 73. The feed line 71 includes a plurality of fault indicators 81-87. When feed line 71 has a fault 9, a fault current is generated between the upstream end 72 and the fault 9 and flows through the fault indicators 81, 82 and 86. In this case, each of the fault indicators 81, 82 and 86 can detect the presence of the fault current and can send the detection result to a processing center (not shown). The processing center locates the fault 9 in the network 7 according to the path of the fault current.

Generally, the processing center integrates the network topology formed by the power network and the fault indicators as graphical information. A worker in the processing center inspects the graphical information one by one with respect to the status and relative position of each fault indicator to locate the fault. In an actual power network, the distribution of the network topology is wide and complex such that inspection of the status of each fault indicator based on the graphical information can not rapidly locate the fault in the power network.

Furthermore, when the power network 7 has two faults 9a and 9b (FIG. 2), a fault current is generated between the upstream end 72 and the fault 9a, and another fault current is generated between the upstream end 72 and the other fault 9b. The fault current related to the fault 9a flows through fault indicators 81, 82 and 86. The fault current related to the other fault 9b flows through fault indicators 81, 82 and 83. Namely, each of the fault indicators 81, 82, 83 and 86 can detect a fault current.

Specifically, when fault currents are generated due to the two faults 9a and 9b in the power network 7, the worker in the processing center must compare each of the fault indicators 81, 82, 83 and 86 detecting the fault current with the graphical information to find out the physical location of the faults 9a and 9b in the power network 7. However, when the processing center is locating the faults 9a and 9b by checking the status of each of the fault indicators 81, 82, 83 and 86 one by one, the fault 9a can only be found by checking the fault indicators 81, 82 and 86 (first checking), and the other fault 9b can only be found by checking the fault indicators 81, 82 and 83 (second checking). Thus, in the conventional fault locating method, the time required for locating the faults is increased if the power network 7 includes more than two faults.

Thus, a need exists for a method for more efficiently locating faults in a power network having a plurality of fault indicators to increase the fault locating speed in the power network.

### SUMMARY OF THE INVENTION

The objective of the present invention is to provide a method for locating faults in a power network having a plurality of fault indicators, wherein the method can increase the fault locating speed in the power network having the fault indicators.

The present invention fulfills the above objective by providing a method for locating faults in a power network having a plurality of fault indicators. The method includes a data reading step, a power network creating step, a fault current vector creating step, and a fault locating step. The data reading step includes reading power network information stored in a database. The power network information includes a power network having at least one feed line. The power network includes an upstream end and a downstream end. A plurality of fault indicators is mounted between the upstream end and the downstream end. The plurality of fault indicators divides the at least one feed line into a plurality of detection zones. The power network matrix creating step includes creating a power network matrix expressed by [Aᵢⱼ]. The number of elements in the power network matrix is equal to the number of the plurality of fault indicators multiplied by the number of the plurality of detection zones. An element Aᵢⱼ in the power network matrix represents an iₜₕ fault indicator and a jₜₕ detection zone. If the iₜₕ fault indicator passes through the jₜₕ detection zone when the iₜₕ fault indicator extends towards the downstream end, the element Aᵢⱼ in the power network matrix is set to 1. If the iₜₕ fault indicator does not pass through the jₜₕ detection zone when the iₜₕ fault indicator extends towards the downstream end, the element Aᵢⱼ of the power network matrix is set to zero. Both of i and j are positive integers. The fault current vector creating step includes creating a fault current vector expressed by [LCᵢ]. The number of elements in the fault current vector is equal to the number of the plurality of fault indicators. An element LCᵢ in the fault current vector represents the iₜₕ fault indicator. The element LCᵢ in the fault current vector is set to zero if the iₜₕ fault indicator detects no current. The element LCᵢ in the fault current vector is set to a value other than zero if the iₜₕ fault indicator detects a current. The fault locating step includes carrying out a backward substitution on the fault current vector and the power network matrix to obtain a detection zone vector expressed by [PELⱼ]. The number of elements in the detection zone vector is equal to the number of the plurality of detection zones. An element PELⱼ in the detection zone vector represents a jₜₕ detection zone. A fault exists in the jₜₕ detection zone if a value of the element PELⱼ in the detection zone vector is larger than a detection standard value.

In examples, the power network matrix is an upper triangular matrix.

In the fault current vector creating step, the element LCᵢ in the fault current vector is set to 1 if the iₜₕ fault indicator detects the current.

In the fault current vector creating step, the iₜₕ fault indicator detects the current, a zone current value is used to represent the current value detected by the iₜₕ fault indicator, and the element LCᵢ in the fault current vector is set to the zone current value detected by the iₜₕ fault indicator.

In the fault current vector creating step, when the iₜₕ fault indicator detects the current, the element LCᵢ in the fault current vector is set to a current value detected by the iₜₕ fault indicator.

In the fault locating step, the detection standard value is set to zero.

In the fault locating step, the detection standard value is set to be smaller than a maximal value of the plurality of elements in the detection zone vector and is set to be larger than or equal to a second maximal value of the plurality of elements in the detection zone vector.

If an end of the jₜₕ detection zone is connected to the iₜₕ fault indicator and if another end of the jₜₕ detection zone extends towards the downstream end and stops at another fault indicator or any terminal, j is equal to i.

The present invention will become clearer in light of the following detailed description of illustrative embodiments of this invention described in connection with the drawings.

### BRIEF DESCRIPTION OF THE DRAWINGS

FIG. 1 is a schematic view of a conventional power network, with the power network having only one fault.

FIG. 2 is a schematic view of the conventional power network, with the power network having two faults.

FIG. 3a shows a block diagram of an apparatus for carrying out a method for locating faults in a power network having a plurality of fault indicators according to the present invention.

FIG. 3b shows a schematic view illustrating a power network using the method for locating faults in a power network having a plurality of fault indicators according to the present invention.

FIG. 4 is a flowchart of the method for locating faults in a power network having a plurality of fault indicators according to the present invention.

FIG. 5 shows a schematic view illustrating a power network using the method for locating faults in a power network having a plurality of fault indicators according to the present invention, with the power network having two faults.

FIG. 6 shows a schematic view illustrating another power network using the method for locating faults in a power network having a plurality of fault indicators according to the present invention, with the power network having only one fault.

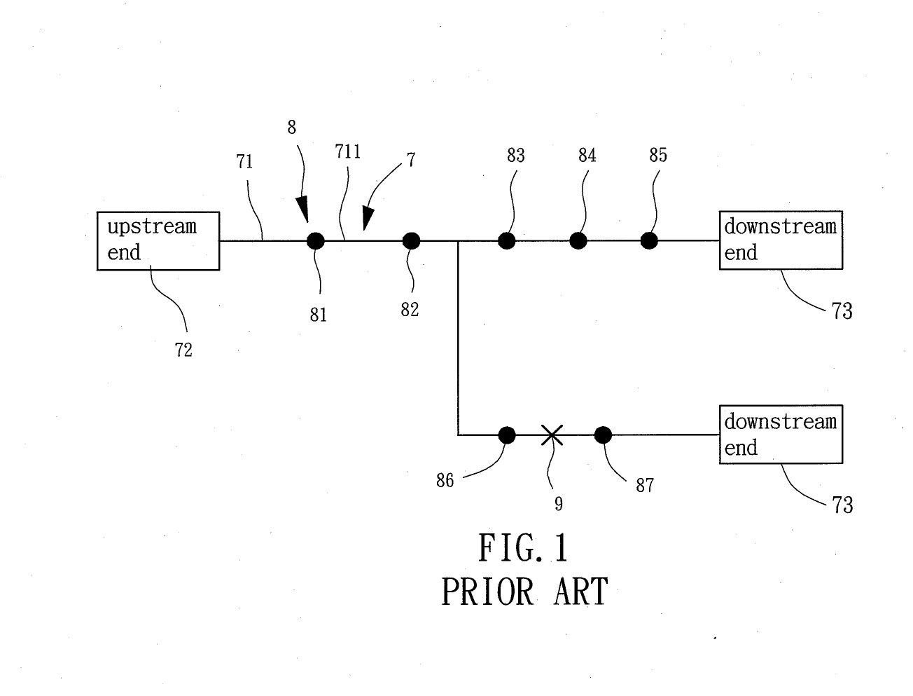

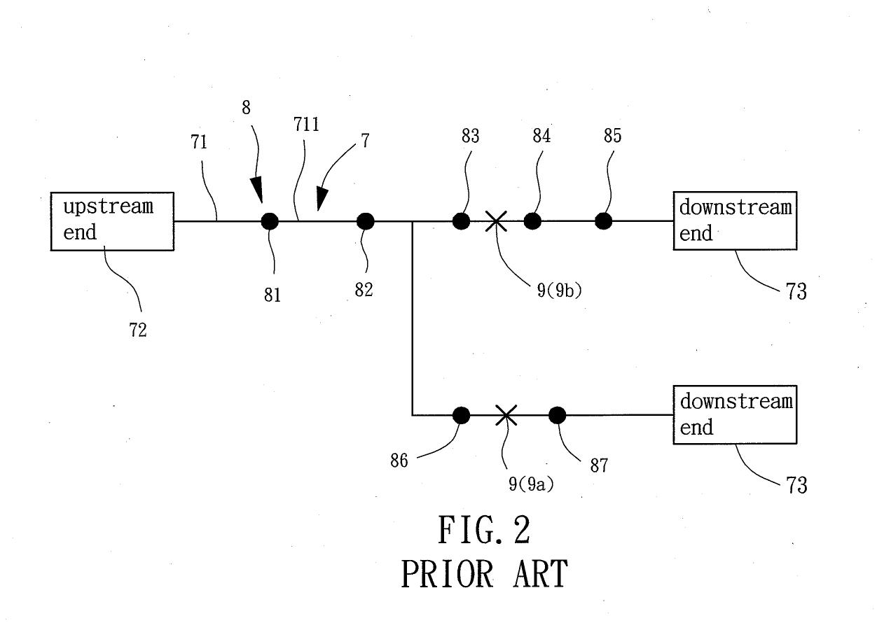

### DETAILED DESCRIPTION OF THE INVENTION

The terms “upstream end” and “downstream end” used herein are determined according to the flowing direction of the power along a power line. Namely, when the power flows from a first end to a second end of a power line, the first end is the upstream end, and the second end is the downstream end.

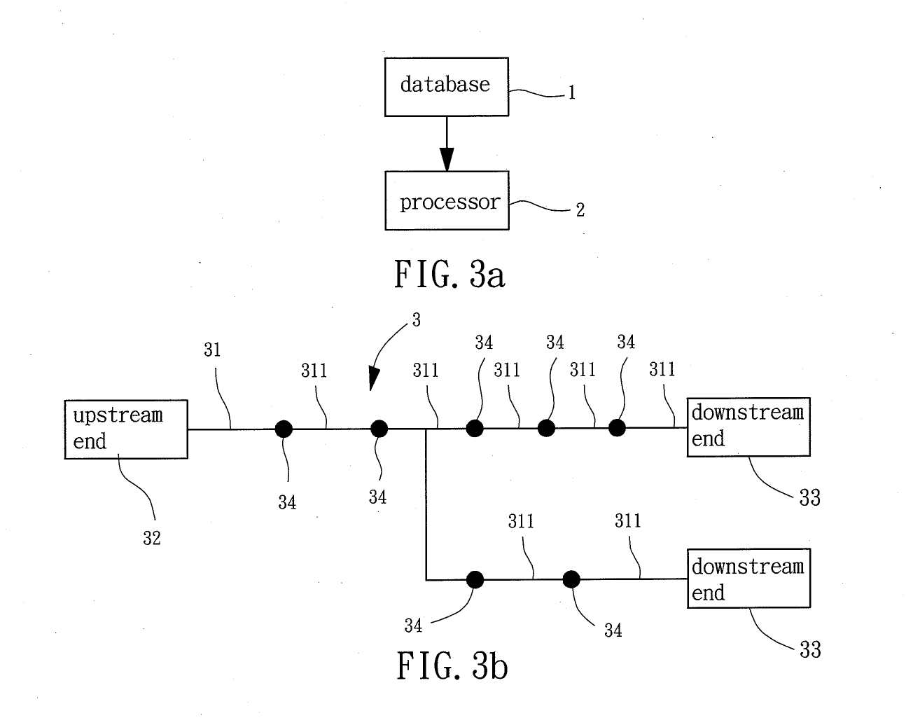

FIGS. 3a and 3b respectively show an apparatus and a power network 3 for carrying out a method for locating faults in a power network having a plurality of fault indicators according to the present invention. Specifically, the apparatus includes a database 1 and a processor 2 and is used in a power network 3. The power network 3 includes at least one feed line 31 having two ends respectively forming an upstream end 32 and a downstream end 33. A plurality of fault indicators 34 is mounted between the upstream end 32 and the downstream end 33. A detection zone 311 is formed between two adjacent fault indicators 34. A section of each feed line 31 between its downstream end 33 and the fault indicator 34 closest to the downstream end 33 also forms a detection zone 311.

The database 1 stores power network information. Specifically, the power network information includes the distribution of each feed line 31 in the power network, the locations of the fault indicators 34 in each feed line 31, and the location of each detection zone 311. The storage and reading patterns of the above data can be information (such as graphical information or coordinate information) combined with a real environment.

The processor 2 is electrically connected to the database 1 for reading the power network information. The processor 2 can be a computer or any operational processor and can execute software or programs to proceed with operations and statistics.

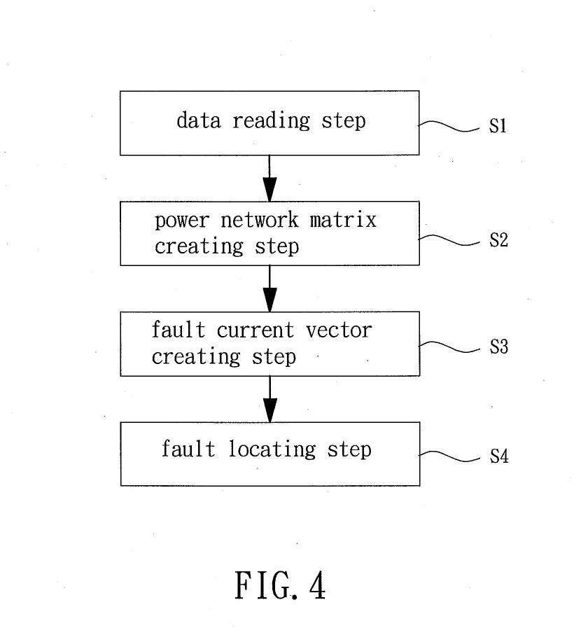

With reference to FIG. 4, the method for locating faults in a power network having a plurality of fault indicators according to the present invention uses the processor 2 to carry out a data reading step S1, a power network matrix creating step S2, a fault current vector creating step S3, and a fault locating step S4.

In the data reading step, the processor 2 reads the power network information stored in the database 1. The power network information includes a power network 3 having at least one feed line 31. The power network 3 includes the upstream end 32 and the downstream end 33. A plurality of fault indicators 34 is mounted between the upstream end 32 and the downstream end 34. The fault indicators 34 divide the at least one feed line 31 into a plurality of detection zones 31, as mentioned above.

More specifically, the processor 2 must firstly read the power network information stored in the database 1 to obtain information including the distribution of each feed line 31 in the power network 3 and the locations of the fault indicators 34 in each feed line 31. Furthermore, each detection zone 311 is formed between two adjacent fault indicators 34 of the feed line 31 or formed by a section of each feed line 31 between its downstream end 33 and the fault indicator 34 closest to the downstream end 33, as mentioned above. As an example, each detection zone 311 includes an end connected to a fault indicator 34, and the other end of each detection end 311 extends towards the downstream end 33 and is connected to another fault indicator 34 or is connected to any terminal (such as a load end or any device mounted on the feed line 31). In this embodiment, the fault indicators 34 can detect current and can detect the direction and the magnitude of the current.

In the power network matrix creating step S2, a power network matrix is created and expressed by [Aᵢⱼ]. The number of elements in the power network matrix [Aᵢⱼ] is equal to the number of the fault indicators 34 multiplied by the number of the plurality of detection zones 311. An element in the power network matrix [Aᵢⱼ] represents the iₜₕ fault indicator 34 and the jₜₕ detection zone 311. If the iₜₕ fault indicator 34 passes through the jₜₕ detection zone 311 when the iₜₕ fault indicator 34 extends towards the downstream end 33, the element Aᵢⱼ in the power network matrix [Aᵢⱼ] is set to 1. On the other hand, if the iₜₕ fault indicator 34 does not pass through the jₜₕ detection zone 311 when the iₜₕ fault indicator 34 extends towards the downstream end 33, the element Aᵢⱼ of the power network matrix [Aᵢⱼ] is set to zero. Both of i and j are positive integers. The maximal value of i is the number of the fault indicators 34. The maximal value of j is the number of the detection zones 311.

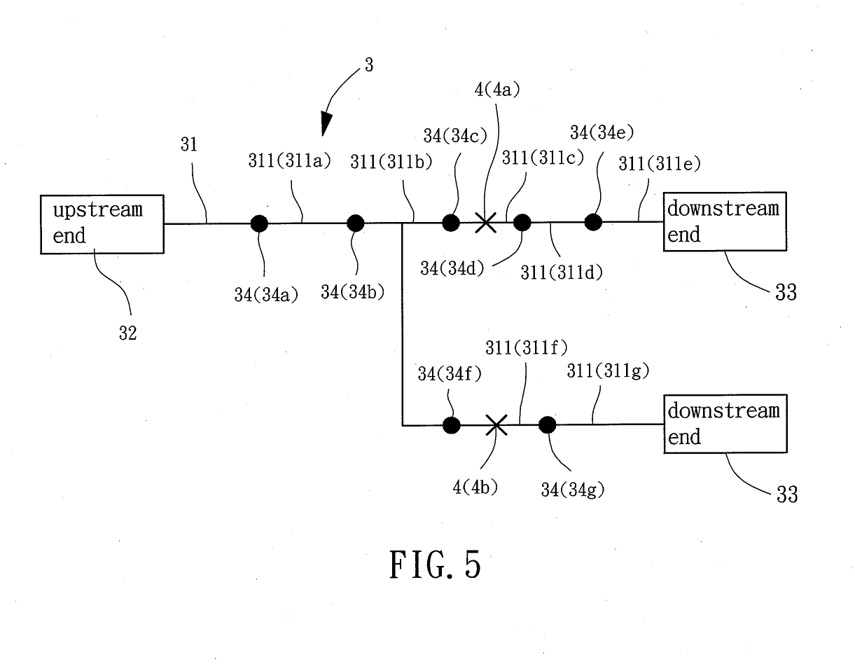

Specifically, the processor 2 creates the power network matrix [Aᵢⱼ] according to the numbers of the detection zones 311 and the fault indicators 34. With reference to FIG. 5, the number of the fault indicators 34a-34g is seven, and the number of the detection zones 311a-311g is also seven. Thus, the number of the elements in the power network matrix [Aᵢⱼ] is 7×7.

The element in the power network matrix [Aᵢⱼ] can be represented by A. If an end of the jₜₕ detection zone 311 is connected to the iₜₕ fault indicator 34 and if the other end of the jₜₕ detection zone 311 extends towards the downstream end 33 and stops at another fault indicator 34 or any terminal (such as the load end or any device mounted on the feed line 31), j=i. If not, j≠i. Specifically, in the example shown in FIG. 5, an end of the detection zone 311a is connected to the fault indicator 34a. The other end of the detection zone 311a extends towards the downstream end 33. Thus, when the fault indicator 34a is regarded as the first fault detector, the detection zone 311a represents the first detection zone. Likewise, the fault indicators 34b-34g are respectively regarded as the second to the seventh fault indicators, and the detection zones 311b-311g respectively represent the second to the seventh detection zones.

Specifically, with regard to the first fault indicator 34a, when the fault indicator 34a extends towards the downstream end 33, the first to seventh detection zones 311a-311g are passed. Thus, the element in the first row of the power network matrix [Aᵢⱼ] can be expressed as follows:

[A₁₁A₁₂ . . . A₁₇]=[1 1 1 1 1 1 1]

With regard to the second fault indicator 34b, when the fault indicator 34b extends towards the downstream end 33, the second to seventh detection zones 311b-311g are passed. Thus, the element in the second row of the power network matrix [Aᵢⱼ] can be expressed as follows:

[A₂₁A₂₂ . . . A₂₇]=[0 1 1 1 1 1 1]

With regard to the third fault indicator 34c, when the fault indicator 34c extends towards the downstream end 33, the third to fifth detection zones 311c-311e are passed. Thus, the element in the third row of the power network matrix [Aᵢⱼ] can be expressed as follows:

[A₃₁A₃₂ . . . A₃₇]=[0 0 1 1 1 0 0]

With regard to the fourth fault indicator 34d, when the fault indicator 34d extends towards the downstream end 33, the fourth and fifth detection zones 311d-311e are passed. Thus, the element in the fourth row of the power network matrix [Aᵢⱼ] can be expressed as follows:

[A₄₁A₄₂ . . . A₄₇]=[0 0 0 1 1 0 0]

With regard to the fifth fault indicator 34e, when the fault indicator 34e extends towards the downstream end 33, only the fifth detection zone 311e is passed. Thus, the element in the fifth row of the power network matrix [Aᵢⱼ] can be expressed as follows:

[A₅₁A₅₂ . . . A₅₇]=[0 0 0 0 1 0 0]

With regard to the sixth fault indicator 34f, when the fault indicator 34f extends towards the downstream end 33, the sixth to seventh detection zones 311f-311g are passed. Thus, the element in the sixth row of the power network matrix [Aᵢⱼ] can be expressed as follows:

[A₆₁A₆₂ . . . A₆₇]=[0 0 0 0 0 1 1]

With regard to the seventh fault indicator 34g, when the fault indicator 34g extends towards the downstream end 33, only the seventh detection zone 311g is passed. Thus, the element in the seventh row of the power network matrix [Aᵢⱼ] can be expressed as follows:

[A₇₁A₇₂ . . . A₇₇]=[0 0 0 0 0 0 1]

Thus, in this embodiment, the power network matrix [Aᵢⱼ] is an upper triangular matrix and can be expressed as follows:

$${[ {A}_{ij} ]}_{7 \times 7} = [ \begin{matrix}1 & 1 & 1 & 1 & 1 & 1 & 1 \\ 0 & 1 & 1 & 1 & 1 & 1 & 1 \\ 0 & 0 & 1 & 1 & 1 & 0 & 0 \\ 0 & 0 & 0 & 1 & 1 & 0 & 0 \\ 0 & 0 & 0 & 0 & 1 & 0 & 0 \\ 0 & 0 & 0 & 0 & 0 & 1 & 1 \\ 0 & 0 & 0 & 0 & 0 & 0 & 1\end{matrix} ]$$

Accordingly, since the power network matrix [Aᵢⱼ] represents the relative locations of the fault indicators 34 and the detection zones 311, the power network matrix [Aᵢⱼ] created in the power network matrix creating step S2 can be used in subsequent operations to increase the fault locating speed of the power network 3.

In the fault current vector creating step S3, a fault current vector is created and expressed by [LCᵢ]. The number of elements in the fault current vector [LCᵢ] is equal to the number of the fault indicators 34. An element LCᵢ in the fault current vector [LCᵢ] represents the iₜₕ fault indicator 34. The element LCᵢ in the fault current vector [LCᵢ] is set to zero if the iₜₕ fault indicator 34 detects no current. The element LCᵢ in the fault current vector [LCᵢ] is set to a value other than zero if the iₜₕ fault indicator 34 detects a current.

Still referring to FIG. 5, in this embodiment, the number of the fault indicators 34a-34g is seven. Thus, there are seven elements in the fault current vector [LCᵢ]. When two faults 4a and 4b are respectively generated in the third detection zone 311c and the sixth detection zone 311f, a fault current is generated between the upstream end 32 and the fault 4a, and another fault current is generated between the upstream end 32 and the other fault 4b. The fault current related to the fault 4a flows through the fault indicators 34a, 34b and 34c. The fault current related to the other fault 4b flows through the fault indicators 34a, 34b, 34c and 34f. The current can be detected at the first, second, third and sixth fault indicators 34a, 34b, 34c and 34f. With regard to the iₜₕ fault indicator 34 detecting the current, LCᵢ can be set to 1 or set to the current value detected by the iₜₕ fault indicator 34. If it is desired to set LCᵢ of the first, second, third and sixth fault indicators 34a, 34b, 34c and 34f detecting the current to 1, the fault current vector [LCᵢ] can be expressed as follows:

[LCᵢ]=[1 1 1 0 0 1 0]^{T}

Since the fault current vector [LCᵢ] represents the current detection result of the fault indicators 34, the fault current vector [LCᵢ] created in the fault current vector creating step S3 and the power network matrix [Aᵢⱼ] can be used to proceed with operations in subsequent steps for increasing the fault locating speed of the power network 3.

In the fault locating step S4, a backward substitution is carried out on the fault current vector [LCᵢ] and the power network matrix [Aᵢⱼ] to obtain a detection zone vector expressed by [PELⱼ]. The number of elements in the detection zone vector [PELⱼ] is equal to the number of the detection zones 311. An element PELⱼ in the detection zone vector [PELⱼ] represents the jₜₕ detection zone. A fault exists in the jₜₕ detection zone if a value of the element PELⱼ in the detection zone vector [PELⱼ] is larger than a detection standard value. Specifically, the operational equation of the fault current vector [LCᵢ], the power network matrix [Aᵢⱼ] and the detection section vector is expressed as follows:

[LCᵢ]=[Aᵢⱼ][PELⱼ]

Accordingly, after the power network matrix [Aᵢⱼ] and the fault current vector [LCᵢ] are known, a backward substitution is carried out to obtain the detection zone vector [PELⱼ]. The detection zone vector [PELⱼ] obtained through the backward substitution is as follows:

[PELⱼ]=[0 |1 1 0 0 1 0]^{T}

In this case, the detection standard value can be set to zero. Namely, a fault exists in the jₜₕ detection zone 311 if the element PELⱼ in the detection zone vector [PELⱼ] is larger than zero. As can be known from the detection zone vector [PELⱼ], the faults are located in the third detection zone 311c and the sixth detection zone 311f. The fault locating result is the same as the locations of the faults 4a and 4b. Thus, it is proven that the fault locating method according to the present invention can accurately and rapidly locate the faults.

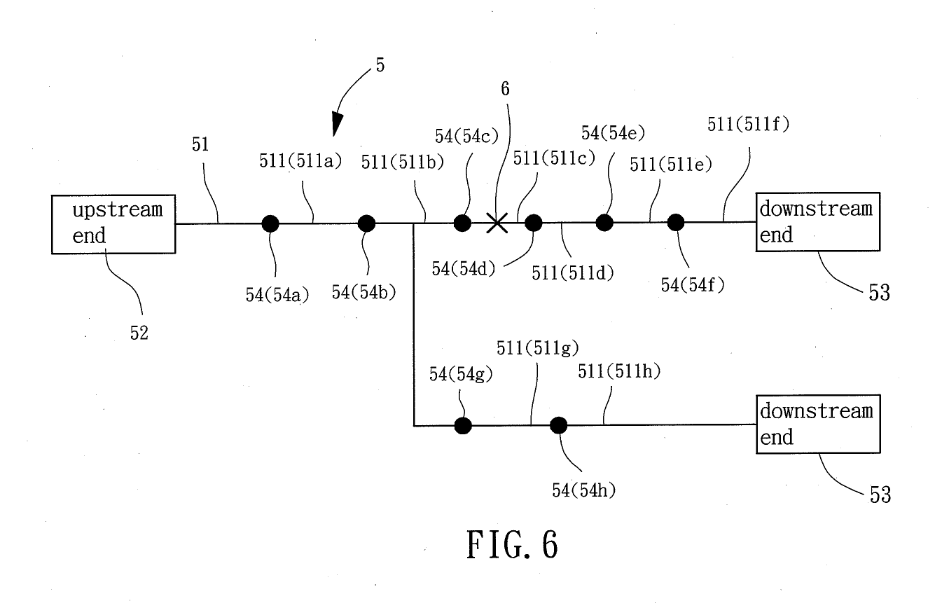

FIG. 6 shows another power network 5 using the method according to the present invention. The power network 5 includes at least one feed line 51 having two ends respectively forming an upstream end 52 and a downstream end 53. A plurality of fault indicators 54 is mounted between the upstream end 52 and the downstream end 53. A detection zone 511 is formed between two adjacent fault indicators 54. In this embodiment, the number of the fault indicators 54a-54h is eight, and the number of the detection zones 511a-511h is eight. In addition to detecting current, each fault indicator 54 can accurately detect the current value of the current flowing therethrough or detect a zone current value of the current flowing therethrough. The unit of the current value or the zone current value can be ampere. Specifically, when an actual current value is between a zone upper limit value and a zone lower limit value, the upper zone limit value is the zone current value if the actual current value is represented by the zone upper limit value. On the other hand, the zone lower limit value is the zone current value if the actual current value is represented by the zone lower limit value.

The data reading step S1 and the power network matrix creating step S2 are carried out in the power network 5 by using the processor 2, which is the same as the first embodiment and, therefore, not be described again to avoid redundancy. After carrying out the power network matrix creating step S2, the power network matrix [Aᵢⱼ] representing the power network 5 is expressed as follows:

$${[ {A}_{ij} ]}_{8 \times 8} = [ \begin{matrix}1 & 1 & 1 & 1 & 1 & 1 & 1 & 1 \\ 0 & 1 & 1 & 1 & 1 & 1 & 1 & 1 \\ 0 & 0 & 1 & 1 & 1 & 1 & 0 & 0 \\ 0 & 0 & 0 & 1 & 1 & 1 & 0 & 0 \\ 0 & 0 & 0 & 0 & 1 & 1 & 0 & 0 \\ 0 & 0 & 0 & 0 & 0 & 1 & 0 & 0 \\ 0 & 0 & 0 & 0 & 0 & 0 & 1 & 1 \\ 0 & 0 & 0 & 0 & 0 & 0 & 0 & 1\end{matrix} ]$$

The fault current vector creating step S3 can be executed after creating the power network matrix [Aᵢⱼ]. In the fault current vector creating step S3, the number of elements in the fault current vector [LCᵢ] is eight, because the number of the fault indicators 54a-54h is eight. In this embodiment, the fault indicators 54a-54h have a plurality of detection zones (375A, 750A, 1500A, 2000A, 4000A, 8000A, respectively). The actual current value flowing through each detection zone 54 is detected. In a case that the actual current value is between the zone upper limit value and the zone lower limit value, the zone lower limit value is used as the zone current value. As an example, if the fault indicator 54 detects a current between 4000-8000 amperes, the zone lower limit value (4000) is used as the zone current value. Thus, the element LCᵢ can be set as the zone current value detected by the iₜₕ fault indicators, and the fault current vector [LCᵢ] can be expressed as follows:

[LCᵢ]=[4000 4000 4000 750 750 0 375 0]^{T}

As can be known from the fault current vector [LCᵢ], the zone current value of the first to third fault indicators 54a-54c is 4000 amperes, and the zone current value of the fourth to eighth fault indicators 54d-54h is far less than the zone current value of the first to third fault indicators 54a-54c. Thus, the zone current value of the fourth to eight fault indicators 54d-54h can be judged. Specifically, the zone current value of the fourth to eighth fault indicators 54d-54h should be a current value of other distributed power sources or a minor fault current contributed by other factors, not the current value of the fault current contributed by the upper stream end 32 of the main power system.

Accordingly, the fault current vector [LCᵢ] can be expressed as the current value or the zone current value detected by each fault indicator 54. Thus, the path of the fault current can be accurately detected by the magnitude of the current value shown by the fault current vector [LCᵢ] or the magnitude of the current value of the zone current value while increasing the fault locating accuracy and the fault locating speed of the power network 5.

The fault locating step S4 is carried out after creating the fault current vector [LCᵢ]. In the fault locating step S4, a backward substitution is carried out to obtain the detection zone vector [PELⱼ]. The detection zone vector [PELⱼ] obtained through the backward substitution is as follows:

[PELⱼ]=[0 −375 3250 0 750 0 375 0]^{T}

In this embodiment, since the fault indicators 54a-54h can detect the current value of the fault current and the current value of the minor fault current contributed by other factors, the detection zone vector [PELⱼ] obtained after calculation in the fault locating step S4 will generate a plurality of different numerical values. In this case, to avoid misjudgment resulting from the presence of the minor current, the detection standard value is preferably set to be smaller than the maximal value of the elements in the detection zone vector [PELⱼ] and is set to be larger or equal to the second maximal value of the elements in the detection zone vector [PELⱼ] to increase the fault locating accuracy. In this embodiment, the detection standard value can be not smaller than 750 and smaller than 3250. When the detection standard value is set to 750, the jₜₕ detection zone 511 has a fault if the element PELⱼ of the detection zone vector [PELⱼ] is larger than 750, Namely, the fault 6 can be located in the third detection zone 511c larger than the detection standard value. The fault locating accuracy and the fault locating speed of the power network 5 are thus increased.

In view of the foregoing, the method for locating faults in a power network 3, 5 having a plurality of fault indicators 34, 54 according to the present invention can create the power network matrix [Aᵢⱼ] according to the relative locations of the fault indicators 34, 54 and the detection zones 311, 511 and can create the fault current vector [LCᵢ] according to the detection results of the fault currents by the fault indicators 34, 54. Then, the faults can be located based on the calculation of the power network matrix [Aᵢⱼ] and the fault current vector [LCᵢ]. Thus, the fault locating speed of the power network 3, 5 can be increased.

Thus since the invention disclosed herein may be embodied in other specific forms without departing from the spirit or general characteristics thereof, some of which forms have been indicated, the embodiments described herein are to be considered in all respects illustrative and not restrictive. The scope of the invention is to be indicated by the appended claims, rather than by the foregoing description, and all changes which come within the meaning and range of equivalency of the claims are intended to be embraced therein.

What is claimed is:

1. A method for locating faults in a power network having a plurality of fault indicators, with the method comprising:
a data reading step including reading power network information stored in a database, with the power network information including a power network having at least one feed line, with the power network including an upstream end and a downstream end, with a plurality of fault indicators mounted between the upstream end and the downstream end, with the plurality of fault indicators dividing the at least one feed line into a plurality of detection zones;
a power network matrix creating step including creating a power network matrix expressed by [Aᵢⱼ], with a number of elements in the power network matrix being equal to a number of the plurality of fault indicators multiplied by a number of the plurality of detection zones, with an element Aᵢⱼ in the power network matrix representing an iₜₕ fault indicator and a jₜₕ detection zone, wherein if the iₜₕ fault indicator passes through the jₜₕ detection zone when the iₜₕ fault indicator extends towards the downstream end, the element Aᵢⱼ in the power network matrix is set to 1, and wherein if the iₜₕ fault indicator does not pass through the jₜₕ detection zone when the iₜₕ fault indicator extends towards the downstream end, the element Aᵢⱼ of the power network matrix is set to zero, wherein both of i and j are positive integers;
a fault current vector creating step including creating a fault current vector expressed by [LCᵢ], with a number of elements in the fault current vector being equal to the number of the plurality of fault indicators, with an element LCᵢ in the fault current vector representing the iₜₕ fault indicator, wherein the element LCᵢ in the fault current vector is set to zero if the iₜₕ fault indicator detects no current, and wherein the element LCᵢ in the fault current vector is set to a value other than zero if the iₜₕ fault indicator detects a current; and
a fault locating step including carrying out a backward substitution on the fault current vector and the power network matrix to obtain a detection zone vector expressed by [PELⱼ], with a number of elements in the detection zone vector being equal to the number of the plurality of detection zones, with an element PELⱼ in the detection zone vector representing a jₜₕ detection zone, wherein a fault exists in the jₜₕ detection zone if a value of the element PELⱼ in the detection zone vector is larger than a detection standard value.

2. The method as claimed in claim 1, wherein the power network matrix is an upper triangular matrix.

3. The method as claimed in claim 1, wherein in the fault current vector creating step, the element LCᵢ in the fault current vector is set to 1 if the iₜₕ fault indicator detects the current.

4. The method as claimed in claim 1, wherein in the fault current vector creating step, when the iₜₕ fault indicator detects the current, a zone current value is used to represent a current value detected by the iₜₕ fault indicator, and the element LCᵢ in the fault current vector is set to the zone current value detected by the iₜₕ fault indicator.

5. The method as claimed in claim 1, wherein in the fault current vector creating step, when the iₜₕ fault indicator detects the current, the element LCᵢ in the fault current vector is set to a current value detected by the iₜₕ fault indicator.

6. The method as claimed in claim 1, wherein in the fault locating step, the detection standard value is set to zero.

7. The method as claimed in claim 1, wherein in the fault locating step, the detection standard value is set to be smaller than a maximal value of the plurality of elements in the detection zone vector and is set to be larger than or equal to a second maximal value of the plurality of elements in the detection zone vector.

8. The method as claimed in claim 1, wherein j is equal to i if an end of the jₜₕ detection zone is connected to the iₜₕ fault indicator and if another end of the jₜₕ detection zone extends towards the downstream end and stops at another fault indicator or any terminal.
